(19) United States
(12) Patent Application Publication
(10) Pub. No.: US 2026/0007054 A1
(43) Pub. Date: Jan. 1, 2026

(54) DISPLAY DEVICE

(71) Applicant: LG Display Co., Ltd., Seoul (KR)

(72) Inventors: In-Tae KO, Gyeonggi-do (KR); Sang-Moo SONG, Gyeonggi-do (KR); Min-Ho LEE, Gyeonggi-do (KR)

(21) Appl. No.: 19/251,645

(22) Filed: Jun. 26, 2025

(30) Foreign Application Priority Data
Jun. 27, 2024 (KR) 10-2024-0084203

(51) Int. Cl. H10K 59/80

(52) U.S. Cl. CPC H10K 59/879; H10K 59/8792

(57) ABSTRACT

A display device includes first, second, and third regions arranged sequentially in a first direction, each of the first, second, and third regions including a plurality of pixels, and the display device includes a display panel including an emission area corresponding to each pixel of the plurality of pixels; and a light control panel over the display panel and including an aperture corresponding to the emission area for each pixel, wherein for pixels located in different portions of the second region, locations of apertures corresponding to the pixels are differently arranged with respect to the emission areas for the pixels.

### CROSS-REFERENCE TO RELATED APPLICATION

Pursuant to 35 U.S.C. § 119(a), this application claims the benefit of an earlier filing date and right of priority to Korean Patent Application No. 10-2024-0084203 filed in the Republic of Korea on Jun. 27, 2024, the entire contents of which are hereby expressly incorporated by reference into the present application.

### TECHNICAL FIELD

The present disclosure relates to a display device.

### BACKGROUND

As the information society progresses, a demand for different types of display devices increases, and flat panel display devices (FPD) such as liquid crystal display devices (LCD) and organic light-emitting diode display devices (OLED) have been developed and applied to various fields.

Among the flat panel display devices, organic light-emitting diode display devices, which are also referred to as organic electroluminescent display devices, emit light due to the radiative recombination of an exciton. The exciton is formed from an electron and a hole by injecting charges into a light-emitting layer between a cathode for injecting electrons and an anode for injecting holes in a light-emitting diode.

### SUMMARY

According to an aspects of the present disclosure, a display device is provided with first, second, and third regions sequentially in a first direction, each of the first, second, and third regions including a plurality of pixels in each region, and the display device includes a display panel including an emission area corresponding to each pixel of the plurality of pixels; and a light control panel over the display panel and including an aperture corresponding to the emission area for each pixel, wherein for pixels located in different portions of the second region, locations of apertures corresponding to the pixels are differently arranged with respect to the emission areas for the pixels.

### BRIEF DESCRIPTION OF THE DRAWINGS

The accompanying drawings, which are included to provide a further understanding of the disclosure and which are incorporated in and constitute a part of this application, illustrate implementations of the disclosure and together with the description serve to explain various principles of the disclosure. In the drawings:

FIG. 1 is a schematic plan view of a display device according to an implementation of the present disclosure;

FIG. 2 is a schematic plan view of enlarging a part of FIG. 1;

FIG. 3 is a cross-sectional view corresponding to the line I-I′ of FIG. 2;

FIG. 4 is a schematic plan view of a display device according to the implementation of the present disclosure applied to a vehicle;

FIG. 5 is a view schematically illustrating the relationship between a viewing position and a viewing angle for a display device according to the implementation of the present disclosure;

FIGS. 6A to 6C are graphs showing luminance characteristics with respect to left and right viewing angles of a display device according to the implementation of the present disclosure;

FIG. 7 is a schematic plan view of a display device according to another implementation of the present disclosure;

FIG. 8 is a schematic plan view of a right shift arrangement of an emission area and an aperture of a display device according to another implementation of the present disclosure;

FIG. 9 is a cross-sectional view corresponding to the line II-II′ of FIG. 8

FIG. 10 is a schematic plan view of a left shift arrangement of an emission area and an aperture of the display device according to another implementation of the present disclosure

FIG. 11 is a cross-sectional view corresponding to the line III-III′ of FIG. 10; and

FIGS. 12A to 12C are graphs showing luminance characteristics with respect to left and right viewing angles for shift arrangements of a display device according to another implementation of the present disclosure.

### DETAILED DESCRIPTION

An organic light-emitting diode display device can be formed over a flexible substrate, such as plastic, and offers various advantages and improved properties. For instance, because it is self-luminous, the organic light-emitting diode display device has an excellent contrast ratio and an ultra-thin thickness, and has a response time of several micro seconds. As such, there are advantages in displaying moving images and videos without delays using the organic light-emitting diode display device.

Additionally, the organic light-emitting diode display device has a wide viewing angle and is stable under low temperatures. Further, since the organic light-emitting diode display device is generally driven by a low voltage of direct current (DC) (e.g., 5V to 15V), it is easy to design and manufacture the driving circuits of the organic light-emitting display device.

As mentioned above, although there is no limit to the viewing angle of the organic light-emitting diode display device, it has recently been desirable to limit the viewing angle for reasons of privacy protection and information protection.

For example, devices such as automated teller machine (ATM) of banking institutions, car navigation systems, laptops, and tablet PCs require limitations of viewing angles in the left, right, up, and down directions for privacy protection.

Accordingly, implementations of the present disclosure are directed to a display device that substantially obviates one or more of the problems due to limitations and disadvantages of the related art.

Implementations of the present disclosure can provide a display device capable of selectively limiting the viewing angle.

Implementations of the present disclosure can provide a display device capable of reducing power consumption and achieving low power consumption by increasing brightness at the maximum viewing angle.

It is to be understood that both the foregoing general description and the following detailed description are examples and explanatory and are intended to provide further explanation of the inventive concepts as claimed.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

Advantages and features of the present disclosure and methods for achieving them will be made clear from implementations described in detail below with reference to the accompanying drawings. The present disclosure can, however, be implemented in many different forms and should not be construed as being limited to the implementations set forth herein, and the implementations are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the implementations of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein or may be briefly discussed.

When terms such as “including,” “having,” “comprising” and the like mentioned in this disclosure are used, other parts can be added unless the term “only” is used herein. Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Features of various implementations of the present disclosure can be partially or entirely united or combined with each other, technically various interlocking and driving are possible, and each of the implementations can be independently implemented with respect to each other or implemented together in a related relationship.

Hereinafter, examples of implementations of the present disclosure will be described in detail with reference to accompanying drawings.

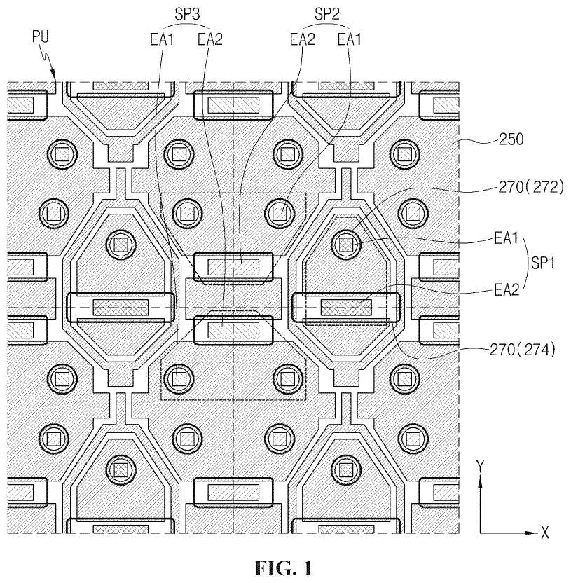

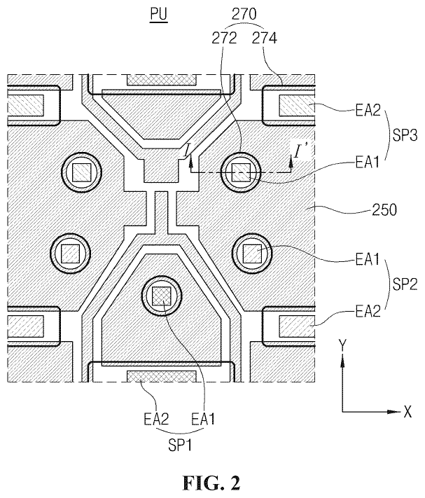

FIG. 1 is a schematic plan view of a display device according to an implementation of the present disclosure, and FIG. 2 is a schematic plan view of enlarging a part of FIG. 1. FIG. 1 shows four pixel units PU, and FIG. 2 shows one pixel unit PU. Here, the pixel unit PU is a unit structure substantially corresponding to one pixel configuration.

As shown in FIG. 1 and FIG. 2, the display device according to an implementation of the present disclosure can include a plurality of pixels, and each pixel can include a plurality of sub-pixels SP1, SP2, and SP3. For example, each pixel can include first, second, and third sub-pixels SP1, SP2, and SP3, and the first, second, and third sub-pixels SP1, SP2, and SP3 can be red, green, and blue sub-pixels, respectively.

The first sub-pixel SP1 can be disposed adjacent to the second and third sub-pixels SP2 and SP3 in a first direction X, and the second sub-pixel SP2 and the third sub-pixel SP3 can be disposed adjacent to each other in a second direction Y crossing the first direction X.

Accordingly, the first sub-pixel SP1 can be disposed between the second sub-pixels SP2 adjacent in the first direction X and between the third sub-pixels SP3 adjacent in the first direction X. The second sub-pixel SP2 and the third sub-pixel SP3 can be disposed between the first sub-pixels SP1 adjacent in the first direction X.

In addition, the second sub-pixel SP2 can be disposed between the third sub-pixels SP3 adjacent in the second direction Y, and the third sub-pixel SP3 can be disposed between the second sub-pixels SP2 adjacent in the second direction Y.

However, implementations of the present disclosure are not limited thereto. In other implementations, the arrangement of the first, second, and third sub-pixels SP1, SP2, and SP3 can vary.

Each of the first, second, and third sub-pixels SP1, SP2, and SP3 can include at least one first emission area EA1 and at least one second emission area EA2. For example, the first sub-pixel SP1 can include one first emission area EA1 and one second emission area EA2, and each of the second and third sub-pixels SP2 and SP3 can include two first emission areas EA1 and one second emission area EA2.

However, implementations of the present disclosure are not limited thereto. In other implementations, the first, second, and third sub-pixels SP1, SP2, and SP3 can include the same number of first emission areas EA1 or different numbers of first emission areas EA1.

The first emission area EA1 and the second emission area EA2 can have different areas. In this case, the area of the second emission area EA2 can be larger than the area of the first emission area EA1. However, implementations of the present disclosure are not limited thereto. In other implementations, the first emission area EA1 and the second emission area EA2 can have the same area, or the area of the first emission area EA1 can be larger than the area of the second emission area EA2.

A lens 270 can be provided to correspond to the first and second emission areas EA1 and EA2. The lens 270 can include a first lens 272 and a second lens 274. The first lens 272 can be disposed to correspond to the first emission area EA1, and the second lens 274 can be disposed to correspond to the second emission area EA2.

The first lens 272 can be a hemispherical lens (e.g., a dome shaped lens), and the second lens 274 can be a semi-cylindrical lens. In this case, the second lens 274 can have a major axis and a minor axis, and the major axis can be arranged parallel to the first direction X.

Meanwhile, a sensor layer 250 can be provided between the first and second emission areas EA1 and EA2 and the first and second lenses 272 and 274.

The sensor layer 250 can include a plurality of patterns. The plurality of patterns can be connected in the first direction X and/or the second direction Y, thereby forming a sensing electrode. The sensing electrode can include a transmitter electrode and a receiver electrode, and a touch input can be detected from the amount of variation in a capacitance between the transmitter electrode and the receiver electrode.

The sensor layer 250 can act as a light-blocking layer that blocks light and can be separated or removed to correspond to each of the first and second emission areas EA1 and EA2, thereby having an aperture.

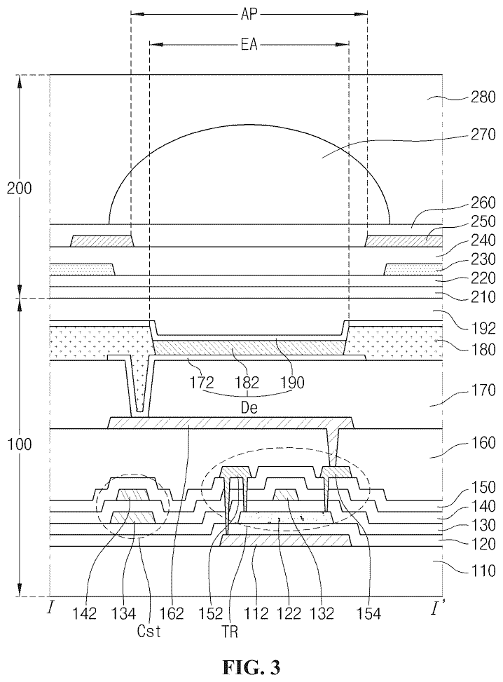

A cross-sectional configuration of the display device according to the implementation of the present disclosure will be described with reference to FIG. 3.

FIG. 3 is a cross-sectional view corresponding to the line I-I′ of FIG. 2. FIG. 3 shows a cross-section of one emission area and will be described with reference to FIG. 2 together. Here, FIG. 3 shows a configuration corresponding to the first emission area EA1. In the display device according to the implementation of the present disclosure, since the configuration corresponding to the first emission area EA1 and the configuration corresponding to the second emission area EA2 can have substantially the same cross-section, the description of the configuration corresponding to the first emission area EA1 can also be applied to the configuration corresponding to the second emission area EA2.

As shown in FIG. 3, the display device according to the implementation of the present disclosure can include a display panel 100 and a light control panel 200 over the display panel 100.

The display panel 100 can include a light-emitting diode De constituting an emission area EA and a thin film transistor TR on a substrate 110. The light control panel 200 can include a sensor layer 250 constituting an aperture AP and a lens 270. The lens 270 can correspond to the aperture AP. Light emitted from the emission area EA of the display panel 100 can be output to the outside through the aperture AP of the light control panel 200, and a viewing angle can be limited by the lens 270.

Meanwhile, the display panel 100 can further include a storage capacitor Cst, and the light control panel 200 can further include a black matrix 230.

Specifically, the substrate 110 of the display panel 100 can be formed of a transparent insulating material and, for example, can be a glass substrate or a plastic substrate. Polyimide can be used for the plastic substrate, and the plastic substrate can have a stacked structure including at least one polyimide layer and at least one inorganic layer. However, implementations of the present disclosure are not limited thereto.

A light-shielding pattern 112 can be provided over and in direct contact with the substrate 110. The light-shielding pattern 112 can be formed of a conductive material such as metal. The light-shielding pattern 112 can be formed of one or more of: aluminum (Al), copper (Cu), molybdenum (Mo), titanium (Ti), chromium (Cr), nickel (Ni), tungsten (W), and an alloy thereof. For example, the light-shielding pattern 112 can have a single-layered structure or a multiple-layered structure.

A barrier layer can be further provided between the substrate 110 and the light-shielding pattern 112. The barrier layer can be formed of an inorganic insulating material, such as silicon oxide (SiOx), silicon nitride (SiNx), or silicon oxynitride (SiON), and can be formed as a single layer or multiple layers.

A buffer layer 120 can be provided over the light-shielding pattern 112. The buffer layer 120 can be formed of an inorganic insulating material, such as silicon oxide (SiOx), silicon nitride (SiNx), or silicon oxynitride (SiON), and can be formed as a single layer or multiple layers.

A semiconductor layer 122 can be provided over the buffer layer 120. The semiconductor layer 122 can overlap the light-shielding pattern 112, and the light-shielding pattern 112 can block light incident on the semiconductor layer 122, and reduce or prevent the semiconductor layer 122 from deteriorating due to the light.

The semiconductor layer can include a channel region of the central portion and source and drain regions on both sides of the channel region. The semiconductor layer 122 can be formed of an oxide semiconductor material. Alternatively, the semiconductor layer 122 can be formed of polycrystalline silicon. In this case, both end portions of the semiconductor layer 122 can be doped with impurities.

A gate insulation layer 130 can be provided over the semiconductor layer 122. The gate insulation layer 130 can be formed of an inorganic insulating material, such as silicon oxide (SiOx), silicon nitride (SiNx), or silicon oxynitride (SiON), and can be formed as a single layer or multiple layers.

A gate electrode 132 and a first capacitor electrode 134 can be provided over the gate insulation layer 130.

The gate electrode 132 can overlap the semiconductor layer 122 and can be disposed to correspond to the central portion of the semiconductor layer 122. Accordingly, the gate electrode 132 can overlap the light-shielding pattern 112.

The first capacitor electrode 134 can be spaced apart from the gate electrode 132. The first capacitor electrode 134 can also be spaced apart from the light-shielding pattern 112.

However, implementations of the present disclosure are not limited thereto. In other implementations, the first capacitor electrode 134 can be in contact with the gate electrode 132 and be electrically connected to the gate electrode 132.

The gate electrode 132 and the first capacitor electrode 134 can be formed of a conductive material such as metal. The gate electrode 132 and the first capacitor electrode 134 can be formed of one or more of: aluminum (Al), copper (Cu), molybdenum (Mo), titanium (Ti), chromium (Cr), nickel (Ni), tungsten (W), and an alloy thereof. The gate electrode 132 and the first capacitor electrode 134 can have a single-layered structure or a triple-layered structure.

A first interlayer insulation layer 140 can be provided over the gate electrode 132 and the first capacitor electrode 134. The first interlayer insulation layer 140 can be formed of an inorganic insulating material, such as silicon oxide (SiOx), silicon nitride (SiNx), or silicon oxynitride (SiON), and can be formed as a single layer or multiple layers.

A second capacitor electrode 142 can be provided over the first interlayer insulation layer 140. The second capacitor electrode 142 can overlap the first capacitor electrode 134 to thereby form the storage capacitor Cst.

The second capacitor electrode 142 can be formed of a conductive material such as metal. The second capacitor electrode 142 can be formed of one or more of: aluminum (Al), copper (Cu), molybdenum (Mo), titanium (Ti), chromium (Cr), nickel (Ni), tungsten (W), and an alloy thereof. For example, the second capacitor electrode 142 can have a single-layered structure or a multiple-layered structure.

A second interlayer insulation layer 150 can be provided over the second capacitor electrode 142. The second interlayer insulation layer 150 can be formed of an inorganic insulating material, such as silicon oxide (SiOx), silicon nitride (SiNx), or silicon oxynitride (SiON), and can be formed as a single layer or multiple layers.

Source and drain electrodes 152 and 154 can be provided over the second interlayer insulation layer 150. The source and drain electrodes 152 and 154 can be spaced apart from each other with the gate electrode 132 positioned therebetween and can be in contact with the both end portions of the semiconductor layer 122 through contact holes provided in the first and second interlayer insulation layers 140 and 150 and the gate insulation layer 130.

In addition, the source electrode 152 can be in contact with the light-shielding pattern 112 through a contact hole provided in the first and second interlayer insulation layers 140 and 150, the gate insulation layer 130, and the buffer layer 120.

The source and drain electrodes 152 and 154 can be formed of one or more of: aluminum (Al), copper (Cu), molybdenum (Mo), titanium (Ti), chromium (Cr), nickel (Ni), tungsten (W), and an alloy thereof. The source and drain electrodes 152 and 154 can have a single-layered structure or a triple-layered structure.

The source and drain electrodes 152 and 154, the semiconductor layer 122, the gate insulation layer 130 and the gate electrode 132 can form a thin film transistor TR.

Meanwhile, one of the first and second interlayer insulation layers 140 and 150 can be omitted, and in this case, the second capacitor electrode 142 can be provided of the same material and on the same layer as the source and drain electrodes 152 and 154.

A first planarization layer 160 can be provided over the source and drain electrodes 152 and 154. The first planarization layer 160 can eliminate a step difference due to the layers thereunder and can have a substantially flat top surface. The first planarization layer 160 can be formed of an organic insulating material such as photosensitive acrylic polymer (photo acryl).

A connection electrode 162 can be provided over the first planarization layer 160. The connection electrode 162 can be in contact with the drain electrode 154 through a contact hole provided in the first planarization layer 160.

The connection electrode 162 can overlap the thin film transistor TR and the storage capacitor Cst. However, implementations of the present disclosure are not limited thereto. In other implementations, the connection electrode 162 can overlap a part of the thin film transistor TR and be in spaced apart from the storage capacitor Cst.

The connection electrode 162 can be formed of a conductive material such as metal. The connection electrode 162 can be formed of one or more of: aluminum (Al), copper (Cu), molybdenum (Mo), titanium (Ti), chromium (Cr), nickel (Ni), tungsten (W), and an alloy thereof. For example, the connection electrode 162 can have a single-layered structure or a multiple-layered structure.

A second planarization layer 170 can be provided over the connection electrode 162. The second planarization layer 170 can eliminate a step difference due to the layers thereunder and can have a substantially flat top surface. The second planarization layer 170 can be formed of an organic insulating material such as photosensitive acrylic polymer (photo acryl).

A first electrode 172 can be provided over the second planarization layer 170 and can be formed of a conductive material having relatively high work function. The first electrode 172 can be in contact with the connection electrode 162 through a contact hole provided in the second planarization layer 170. Accordingly, the first electrode 172 can be electrically connected to the drain electrode 154 through the connection electrode 162.

Alternatively, the connection electrode 162 and the second planarization layer 170 can be omitted. In this case, the first electrode 172 can be in direct contact with the drain electrode 154.

For example, the first electrode 172 can include a transparent conductive material such as indium tin oxide (ITO) or indium zinc oxide (IZO) or include titanium (Ti). However, implementations of the present disclosure are not limited thereto.

Meanwhile, the first electrode 172 can have a multi-layered structure including a material with relatively high reflectance. For example, the first electrode 172 can be formed as a structure having relatively high reflectance such as a triple-layered structure of titanium, aluminum, and titanium (Ti/Al/Ti), a triple-layered structure of indium tin oxide, aluminum, and indium tin oxide (ITO/Al/ITO), a triple-layered structure of indium tin oxide, silver, and indium tin oxide (ITO/Ag/ITO), or a triple-layered structure of indium tin oxide, silver alloy, and indium tin oxide (ITO/Ag alloy/ITO). Here, the silver alloy can be an alloy of silver-palladium-copper (APC).

A bank 180 of an organic insulating material can be provided over the first electrode 172. The bank 180 can overlap edges of the first electrode 172 and cover the edges of the first electrode 172. The bank 180 can expose a central portion of the first electrode 172.

Next, a light-emitting layer 182 can be provided over the first electrode 172 exposed by the bank 180. The light-emitting layer 182 can emit one of red, green, and blue lights.

The light-emitting layer 182 can include at least one hole auxiliary layer, at least one light-emitting material layer, and at least one electron auxiliary layer constituting one light-emitting unit.

The light-emitting material layer can include one of red, green, and blue luminescent materials. The luminescent material can be an organic luminescent material such as a phosphorescent compound or a fluorescent compound or can be an inorganic luminescent material such as a quantum dot.

The hole auxiliary layer can include at least one of a hole injection layer (HIL) and a hole transport layer (HTL). The electron auxiliary layer can include at least one of an electron injection layer (EIL) and an electron transport layer (ETL).

As shown in the figure, the light-emitting layer 182 can be disposed only on the first electrode 172 exposed by the bank 180. However, implementations of the present disclosure are not limited thereto. In other implementations, some of the light-emitting layer 182, for example, the light-emitting material layer can be disposed only on the first electrode 172, and the hole auxiliary layer and the electron auxiliary layer can be disposed substantially all over the substrate 110.

Alternatively, the light-emitting layer 182 can emit white light and can be provided on top and side surfaces of the bank 180, so that the light-emitting layer 182 can be disposed substantially all over the substrate 110. In this case, the light-emitting layer 182 can include a plurality of light-emitting units emitting light of different colors and being stacked. Each stack can include at least one hole auxiliary layer, at least one light-emitting material layer, and at least one electron auxiliary layer.

For example, the light-emitting layer 182 can have a stack structure in which two or more light-emitting units emitting different colors are stacked, and a charge generation layer (CGL) can be provided between two or more light-emitting units.

A second electrode 190 of a conductive material with relatively low work function can be provided over the light-emitting layer 182. The second electrode 190 can be disposed substantially all over the substrate 110.

The second electrode 190 can be formed of aluminum (Al), magnesium (Mg), silver (Ag), or an alloy thereof. In this case, the second electrode 190 can have a relatively thin thickness such that light from the light-emitting layer 182 can be transmitted therethrough. For example, the second electrode 190 can have a thickness of 5 nm to 10 nm, but implementations of the present disclosure are not limited thereto.

Alternatively, the second electrode 190 can be formed of a transparent conductive material such as indium gallium oxide (IGO) or IZO.

The first electrode 172, the light-emitting layer 182, and the second electrode 190 can constitute the light-emitting diode De. Here, the first electrode 172 can serve as an anode, and the second electrode 190 can serve as a cathode. However, implementations of the present disclosure are not limited thereto. In other implementations, the first electrode 172 can serve as a cathode, and the second electrode 190 can serve as an anode.

The light-emitting diode De can constitute the emission area EA where light is emitted, and the emission area EA can be defined by the bank 180. That is, the emission area EA can correspond to the first electrode 172 exposed by the bank 180 and can be surrounded by the bank 180.

An encapsulation layer 192 can be provided over the second electrode 190 and disposed substantially all over the substrate 110. The encapsulation layer 192 can protect the light-emitting diode De from external moisture or oxygen. The encapsulation layer 192 can include at least one inorganic layer and at least one organic layer. Here, the organic layer can be a layer covering particles that are generated during the manufacturing process.

Meanwhile, although not shown in the figure, a capping layer can be provided between the second electrode 190 and the encapsulation layer 192. The capping layer can be formed of an insulating material having a relatively high refractive index. The wavelength of light traveling along the capping layer can be amplified by surface plasma resonance. Thus, the intensity of the peak can be increased, thereby improving the light efficiency in the display device. For example, the capping layer can be formed as a single layer of an organic layer or an inorganic layer, or can be formed as organic/inorganic stacked layers.

Next, a first buffer layer 210 and a second buffer layer 220 of the light control panel 200 can be sequentially provided over the encapsulation layer 192. Each of the first buffer layer 210 and the second buffer layer 220 can be formed of an inorganic insulating material, such as silicon oxide (SiOx), silicon nitride (SiNx), or silicon oxynitride (SiON), and can be formed as a single layer or multiple layers.

Meanwhile, a bridge electrode can be provided between the first buffer layer 210 and the second buffer layer 220. The bridge electrode can be selectively in contact with the plurality of patterns of the sensor layer 250 and can connect the plurality of patterns of the sensor layer 250 in the first direction X and/or the second direction Y.

The bridge electrode can be formed of a conductive material such as metal. The bridge electrode can be formed of one or more of: aluminum (Al), copper (Cu), molybdenum (Mo), titanium (Ti), chromium (Cr), nickel (Ni), tungsten (W), and an alloy thereof. For example, the bridge electrode can have a single-layered structure or a multiple-layered structure.

A black matrix 230 can be provided over the second buffer layer 220. The black matrix 230 can be formed of a black resin absorbing light. For example, the black resin can include a black pigment and/or carbon black. However, implementations of the present disclosure are not limited thereto.

An interlayer insulation layer 240 can be provided over the black matrix 230. The interlayer insulation layer 240 can be formed of an organic insulating material such as photosensitive acrylic polymer (photo acryl).

The sensor layer 250 can be provided over the interlayer insulation layer 240. The sensor layer 250 can include the plurality of patterns. The plurality of patterns can be selectively connected to each other through the bridge electrode in the first direction X and/or the second direction Y, thereby forming the sensing electrode.

The sensor layer 250 can act as a light-blocking layer that blocks light. The sensor layer 250 can be separated or removed to correspond to the emission area EA, thereby forming the aperture AP.

Meanwhile, the black matrix 230 can be removed to correspond to the emission area EA, thereby having an opening. The black matrix 230 can be disposed between the light-blocking layer, i.e., the sensor layer 250 and the display panel 100. The opening of the black matrix can be larger than the aperture AP of the sensor layer 250. The opening of the black matrix 230 can have a greater width and area than the aperture AP of the sensor layer 250.

The sensor layer 250 can be formed of a conductive material such as metal. The sensor layer 250 can be formed of one or more of: aluminum (Al), copper (Cu), molybdenum (Mo), titanium (Ti), chromium (Cr), nickel (Ni), tungsten (W), and an alloy thereof. For example, the sensor layer 250 can have a single-layered structure or a multiple-layered structure.

A passivation layer 260 can be provided over the sensor layer 250. The passivation layer 260 can be formed of an inorganic insulating material, such as silicon oxide (SiOx), silicon nitride (SiNx), or silicon oxynitride (SiON), and can be formed as a single layer or multiple layers.

The lens 270 can be provided over the passivation layer 260. The lens 270 can correspond to the emission area EA and output light emitted from the emission area EA at a specific angle, thereby limiting the viewing angle. The lens 270 can have a wider width than the aperture AP.

A protection layer 280 can be provided over the lens 270 and can protect the lens 270. The protection layer 280 can be formed of an organic insulating material and can have a substantially flat top surface. The refractive index of the protection layer 280 can be smaller than the refractive index of the lens 270.

The protection layer 280 can be formed of an organic insulating material such as photosensitive acrylic polymer (photo acryl), benzocyclobutene (BCB), polyimide (PI) or polyamide (PA), but implementations of the present disclosure are not limited thereto.

Meanwhile, although not shown in the figure, a polarizing plate can be provided over the protection layer 280. The polarizing plate can include a linear polarizing layer and a retardation layer. The polarizing plate can change the polarizing state of the external light incident on the display panel 100, so that the external light can be prevented from being output to the outside after being reflected in the display panel 100.

In the display device according to the implementation of the present disclosure, by providing the lens 270 to correspond to the emission area EA, light can be concentrated by the lens 270 and output to the outside in a specific direction, thereby limiting the viewing angle.

As described above, the lens 270 can include the first lens 272 corresponding to the first emission area EA1 and the second lens 274 corresponding to the second emission area EA2 of FIG. 2. The first lens 272 can be a hemispherical lens (e.g., a dome shaped lens), and the second lens 274 can be a semi-cylindrical lens.

The first lens 272 and the second lens 274 can limit the viewing angle in different directions. The hemispherical first lens 272 can have a narrow viewing angle less than a specific angle in both the first direction X and the second direction Y The semi-cylindrical second lens 274 can have a wide viewing angle more than the specific angle in the first direction X and a narrow viewing angle less than the specific angle in the second direction Y That is, the second lens 274 can have the maximum viewing angle in the first direction X greater than the maximum viewing angle in the second direction Y.

Accordingly, the display device according to the implementation of the present disclosure can implement the wide viewing angle and the narrow viewing angle by selectively driving the first emission area EA1 and the second emission area EA2.

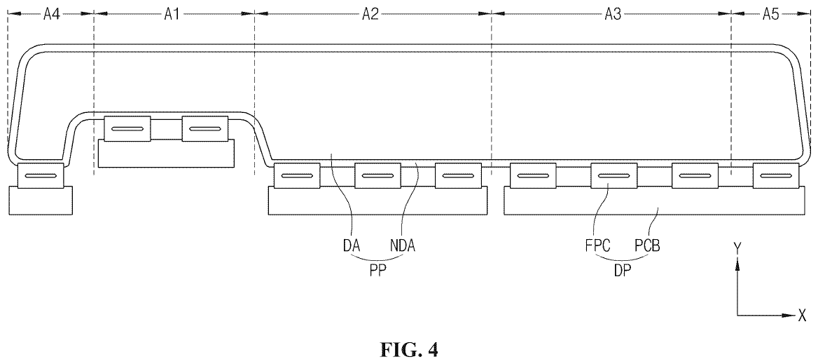

The display device according to the implementation of the present disclosure can be applied to a vehicle. A display device according to the implementation of the present disclosure applied to a vehicle will be described with reference to FIG. 4.

FIG. 4 is a schematic plan view of a display device according to the implementation of the present disclosure applied to a vehicle.

In FIG. 4, the display device according to the implementation of the present disclosure can include a panel part PP and a driving part DP.

The panel part PP can include a display area DA displaying an image and a non-display area NDA surrounding the display area DA. A plurality of pixels can be provided in the display area DA. The driving part DP can be connected to the non-display area NDA.

The pixel provided in the display area DA can have a planar or cross-sectional configuration of FIGS. 1 to 3.

The driving part DP can include a flexible printed circuit FPC and a printed circuit board PCB. The flexible printed circuit FPC can include a base film formed of a flexible material and a driver integrated circuit chip (driver IC chip) mounted on the base film. The flexible printed circuit FPC can generate a gate signal and a data signal for displaying an image and transmit the gate signal and the data signal to the panel part PP.

The flexible printed circuit FPC can be a chip on film (COF) type. However, implementations of the present disclosure are not limited thereto. In other implementations, the flexible printed circuit FPC can be a chip on glass (COG) type or a tape carrier package (TCP) type.

The printed circuit board PCB can include a circuit portion controlling the driver IC chip. For example, the printed circuit board PCB can include a timing controller that receives an image signal and a plurality of timing signals from an external system, generates a plurality of control signals, and transmits the generated control signals to the driver IC chip.

In the display device according to the implementation of the present disclosure, the panel part PP can include a plurality of regions in the first direction X.

Specifically, the panel part PP of the display device according to the implementation of the present disclosure can include first, second, and third regions A1, A2, and A3 sequentially arranged in the first direction X, and the second region A2 can be disposed between the first region A1 and the third region A3.

The first region A1 can correspond to a cluster and can provide information such as driving speed, RPM, engine temperature, and fuel amount. The second region A2 can correspond to a center information display (CID) and can provide various convenient functions such as audio, video, navigation, air conditioning, and Bluetooth. The third region A3 can correspond to a co-driver display (CDD) and can provide entertainment functions and seat information for a passenger seated in the front passenger seat.

In addition, the panel part PP of the display device according to the implementation of the present disclosure can further include a fourth region A4 and a fifth region A5. The fourth region A4 and the fifth region A5 can correspond to side mirrors. The fourth region A4 can be provided on a left side of the first region A1, and the fifth region A5 can be provided on a right side of the third region A3. Accordingly, the first, second, and third regions A1, A2, and A3 can be disposed between the fourth region A4 and the fifth region A5.

Since the display device according to the implementation of the present disclosure can always have a narrow viewing angle in an up-down direction parallel to the second direction Y, that is, the vertical direction, when the display device is applied to a vehicle, an image can be prevented from being reflected on the windscreen of the vehicle and obstructing the driver's view.

Meanwhile, the display device according to the implementation of the present disclosure can selectively display an image of a wide viewing angle and an image of a narrow viewing angle in a left-right direction parallel to the first direction X, that is, the horizontal direction, so that both the driver and the passenger can view an image or one of the driver and the passenger can view an image of a specific region.

Accordingly, the display device according to the implementation of the present disclosure can selectively limit the viewing angle in the horizontal direction.

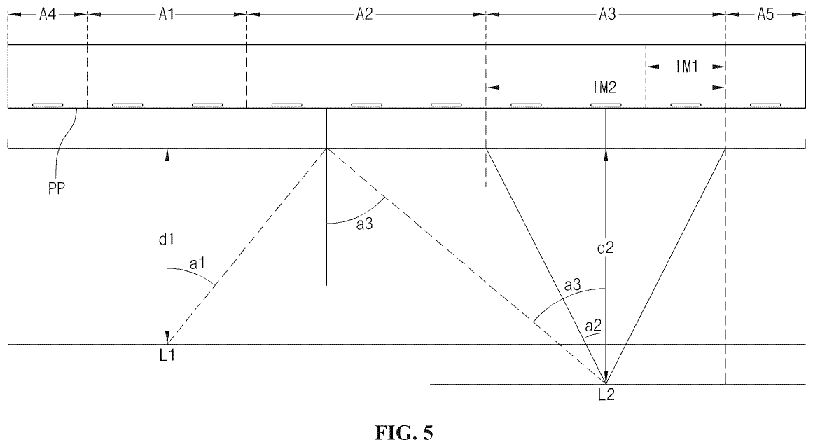

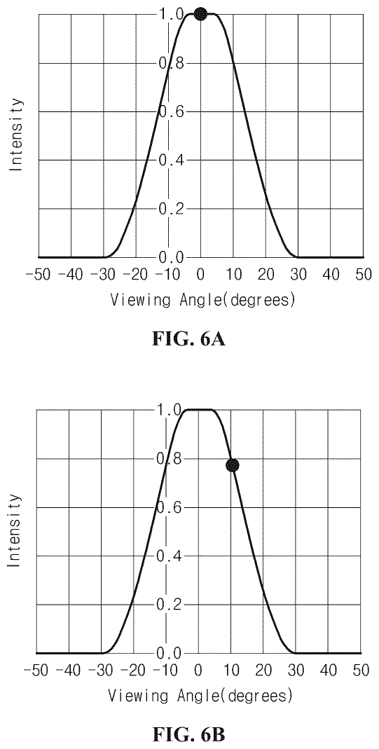

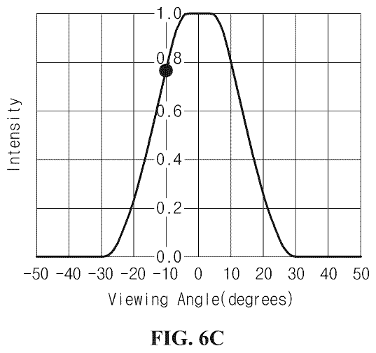

In the display device according to the implementation of the present disclosure, horizontal viewing angle characteristics of the driver and the passenger will be described with reference to FIG. 5 and FIGS. 6A to 6C.

FIG. 5 is a view schematically illustrating the relationship between a viewing position and a viewing angle for a display device according to the implementation of the present disclosure.

In FIG. 5, the panel part PP of the display device according to the implementation of the present disclosure can include first, second, third, fourth, and fifth regions A1, A2, A3, A4, and A5. A plurality of pixels can be provided in each of the first, second, third, fourth, and fifth regions A1, A2, A3, A4, and A5, and each pixel can have a planar or cross-sectional configuration of FIGS. 1 to 3.

The driver's position L1 and the passenger's position L2 with respect to the panel part PP can be different. Accordingly, a first distance d1 between the panel part PP and the driver can be different from a second distance d2 between the panel part PP and the passenger, and the first distance d1 can be smaller than the second distance d2.

However, implementations of the present disclosure are not limited thereto. In other implementations, the first distance d1 and the second distance d2 can be the same.

With respect to the display device according to the implementation of the present disclosure, the driver can have a first viewing angle a1, and the passenger can have a second viewing angle a2. Here, the first viewing angle a1 can be greater than the second viewing angle a2. However, implementations of the present disclosure are not limited thereto.

The first viewing angle a1 can be the driver's horizontal viewing angle, and the second viewing angle a2 can be the passenger's horizontal viewing angle. That is, the driver can view an image having a certain level of image quality or higher within the first viewing angle a1, and the passenger can view an image having a certain level of image quality or higher within the second viewing angle a2.

The first viewing angle a1 can correspond to the second region A2 at the driver's position L1, and the second viewing angle a2 can correspond to the boundary of the third region A3 at the passenger's position L2.

Meanwhile, the passenger can have a third viewing angle a3 corresponding to the second region A2. Here, the third viewing angle a3 can be the maximum viewing angle of the passenger. That is, the passenger can view an image within the third viewing angle a3 and cannot view an image outside the third viewing angle a3.

FIGS. 6A to 6C are graphs showing luminance characteristics with respect to left and right viewing angles of a display device according to the implementation of the present disclosure and will be described with reference to FIGS. 1 to 5 together. Here, the horizontal axis of the graph represents the viewing angles, and the vertical axis represents the intensity of light. The intensity of light can be a normalized relative value in arbitrary units (A.U.).

At this time, the luminance characteristics can be explained based on the viewing area of the passenger, that is, the third region A3. The point on the graph of FIG. 6A can correspond to the luminance characteristic at the front of the viewing area, the point on the graph of FIG. 6B can correspond to the luminance characteristic at the left edge of the viewing area, and the point on the graph of FIG. 6C can correspond to the luminance characteristic at the right edge of the viewing area.

In FIGS. 6A to 6C, the display device according to the implementation of the present disclosure can have the luminance of about 100% at the front of the viewing area, the luminance of about 1% at the left and right viewing angles of about 30 degrees, and the luminance of about 77% at the left and right viewing angles of about 10 degrees.

As such, in the display device according to the implementation of the present disclosure, an image having a certain level of image quality or higher can be viewed when the left and right viewing angles are within about 10 degrees, and an image cannot be viewed when the left and right viewing angles are greater than about 30 degrees, thereby implementing the narrow viewing angle in the left-right direction.

Accordingly, referring to FIG. 5 again, when the third region A3 is configured such that the second viewing angle a2 is about 10 degrees, the passenger can view the image of the third region A3 having a certain level of image quality or higher. Here, the minimum luminance for the third region A3 can be about 77%. That is, the luminance at the left and right edges of the third region A3 can be about 77%.

In this case, the passenger can select a part or the whole of the third region A3 depending on a type of the image desired to be viewed. For example, the passenger can select the part of the third region A3 to view an image IM1 of a relatively small screen such as shorts or select the whole of the third region A3 to view an image IM2 of a relatively large screen such as a movie.

In addition, the passenger can view an image up to a certain area of the second region A2. That is, the passenger can view a part of the image of the second region A2 up to the third viewing angle a3. At this time, according to FIGS. 6A to 6C, the third viewing angle a3, which is the maximum viewing angle of the passenger, can be about 30 degrees.

On the other hand, since the third region A3 is out of the maximum viewing angle of the driver, the driver cannot view the image of the third region A3. Accordingly, only the passenger can view the image of the third region A3.

As such, by providing the light control panel 200 over the display panel 100, the display device according to the implementation of the present disclosure can selectively control the left and right viewing angles.

In the display device according to the implementation of the present disclosure, since the image of the third region A3 can only be viewed by the passenger and not the driver, the privacy of the passenger can be protected.

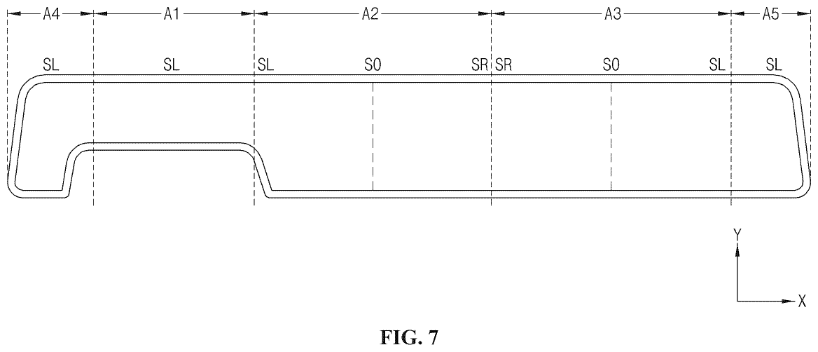

Meanwhile, in another implementation of the present disclosure, by shifting the light control panel 200 to the left or right with respect to the display panel 100 in the second region A2, the privacy of the driver can also be protected. A display device according to another implementation of the present disclosure will be described with reference to FIG. 7. In this case, the black matrix 230, the sensor layer 250, and the lens 270 of the light control panel 200 can be shifted to the left or right with respect to the light-emitting diode De of the display panel 100, and will be described based on the emission area EA and the aperture AP, which are an actual area emitting and outputting light.

FIG. 7 is a schematic plan view of a display device according to another implementation of the present disclosure and will be described with reference to FIGS. 1 to 5 together.

In FIG. 7, the display device according to another implementation of the present disclosure can include a plurality of regions A1, A2, A3, A4, and A5 in the first direction X.

Specifically, the display device according to another implementation of the present disclosure can include first, second, and third regions A1, A2, and A3 sequentially arranged in the first direction X, and the second region A2 can be disposed between the first region A1 and the third region A3. In addition, the display device according to another implementation of the present disclosure can further include a fourth region A4 and a fifth region A5. The fourth region A4 can be provided on a left side of the first region A1, and the fifth region A5 can be provided on a right side of the third region A3. Accordingly, the first, second, and third regions A1, A2, and A3 can be disposed between the fourth region A4 and the fifth region A5.

At this time, in the pixels arranged in the second region A2, positions of the emission area EA and the aperture AP can be different depending on locations.

For example, at least one pixel disposed at the center of the second region A2 can have a zero shift S0 arrangement. That is, as shown in FIG. 2 and FIG. 3, the aperture AP may not shift with respect to the emission area EA.

On the other hand, the pixel disposed at the right edge of the second region A2 can have a right shift SR arrangement. That is, the aperture AP can shift to the right with respect to the emission area EA.

In addition, the pixels disposed between the center and the right edge of the second region A2 can also have the right shift SR arrangement, and the degree of shift can gradually increase from the center to the right edge. That is, the degree of shift of the pixel adjacent to the center can be smallest, and the degree of shift of the pixel disposed at the right edge can be largest.

On the other hand, the pixel disposed at the left edge of the second region A2 can have a left shift SL arrangement. That is, the aperture AP can shift to the left with respect to the emission area EA.

In addition, the pixels disposed between the center and the left edge of the second region A2 can also have the left shift SL arrangement, and the degree of shift can gradually increase from the center to the left edge. That is, the degree of shift of the pixel adjacent to the center can be smallest, and the degree of shift of the pixel disposed at the left edge can be largest.

Here, the pixels of the second region A2 can have a structure that is symmetrical left and right with respect to the pixel arranged in the zero shift S0. In addition, the degrees of shift of the pixels of the second region A2 in the left-right direction, that is, the first direction X can all be different.

However, implementations of the present disclosure are not limited thereto. At least two pixels of the second region A2 adjacent to each other in the first direction X can have the same degree of shift.

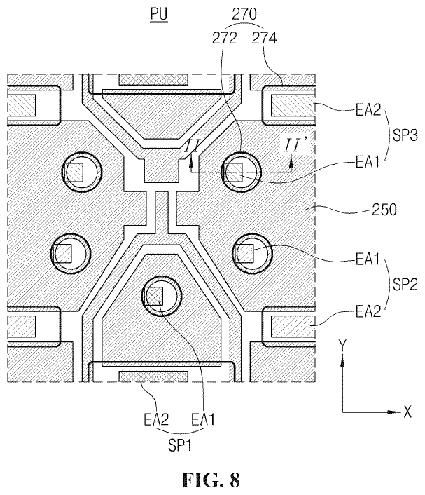

The shift arrangement of the emission area EA and the aperture AP will be described with reference to FIGS. 8 to 11.

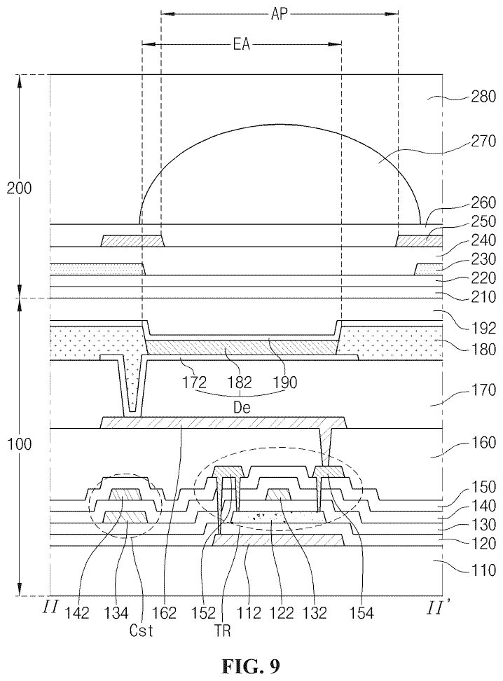

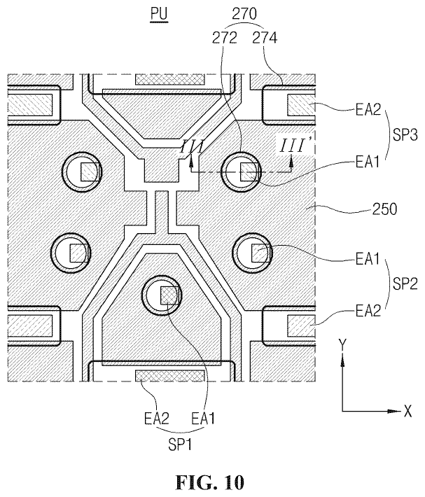

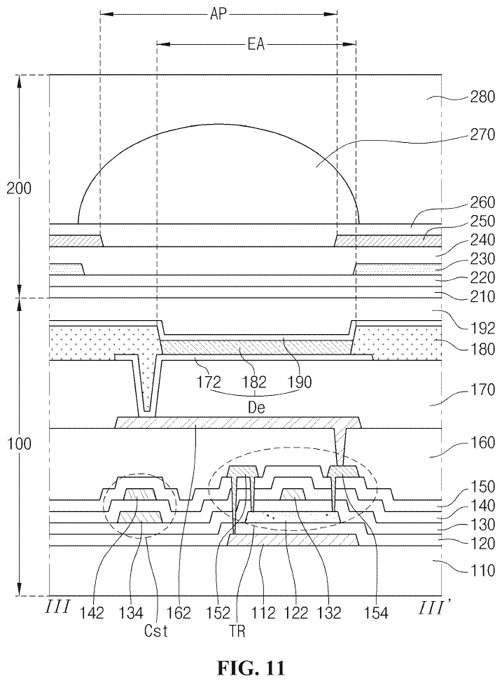

FIG. 8 is a schematic plan view of a right shift arrangement of an emission area and an aperture of a display device according to another implementation of the present disclosure, and FIG. 9 is a cross-sectional view corresponding to the line II-II′ of FIG. 8. FIG. 10 is a schematic plan view of a left shift arrangement of an emission area and an aperture of the display device according to another implementation of the present disclosure, and FIG. 11 is a cross-sectional view corresponding to the line III-III′ of FIG. 10.

As shown in FIG. 8 and FIG. 9, in the case of the right shift SR arrangement, the black matrix 230, the sensor layer 250, and the lens 270 of the light control panel 200 can shift to the right with respect to the light-emitting diode De of the display panel 100. That is, the aperture AP of the light control panel 200 can shift to the right with respect to the emission area EA of the display panel 100. Accordingly, the emission area EA and the aperture AP can partially overlap each other.

In this case, the minimum overlap area of the emission area EA and the aperture AP right-shifted SR can be about 50% of the maximum overlap area, that is, the overlap area of the emission area EA and the aperture AP zero-shifted S0 of FIGS. 2 and 3. In other words, the maximum right shift of the emission area EA and the aperture AP can be about 50%.

Next, as shown in FIG. 10 and FIG. 11, in the case of the left shift SL arrangement, the black matrix 230, the sensor layer 250, and the lens 270 of the light control panel 200 can shift to the left with respect to the light-emitting diode De of the display panel 100. That is, the aperture AP of the light control panel 200 can shift to the left with respect to the emission area EA of the display panel 100. Accordingly, the emission area EA and the aperture AP can partially overlap each other.

In this case, the minimum overlap area of the emission area EA and the aperture AP left-shifted SL can be about 50% of the maximum overlap area, that is, the overlap area of the emission area EA and the aperture AP zero-shifted S0 of FIGS. 2 and 3. In other words, the maximum left shift of the emission area EA and the aperture AP can be about 50%.

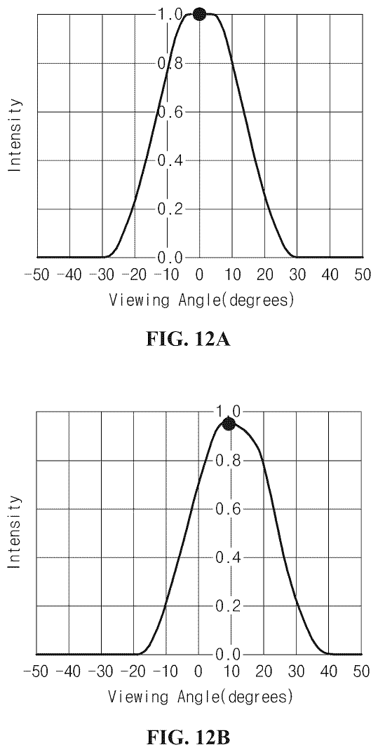

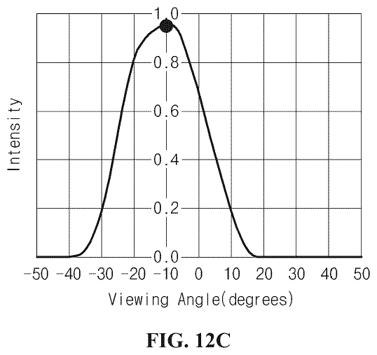

FIGS. 12A to 12C are graphs showing luminance characteristics with respect to left and right viewing angles for shift arrangements of a display device according to another implementation of the present disclosure. FIG. 12A shows the luminance characteristics in a zero shift arrangement, FIG. 12B shows the luminance characteristics in a right shift arrangement, and FIG. 12C shows the luminance characteristics in a left shift arrangement. Here, the horizontal axis of the graph represents the viewing angles, and the vertical axis represents the intensity of light. The intensity of light can be a normalized relative value in arbitrary units (A.U.).

As shown in FIG. 12A, in the zero shift S0 arrangement, the luminance at the front can be about 100%, the luminance at the left and right viewing angles of about 30 degrees can be about 1%, and the luminance at the left and right viewing angles of about 10 degrees can be about 77%.

Meanwhile, as shown in FIG. 12B, in the right shift SR arrangement, the luminance at the angle of about +10 degrees can be the maximum. The maximum luminance can be about 96%, and the luminance at the angles of about +40 degrees and about −20 degrees can be about 1%.

On the other hand, as shown in FIG. 12C, in the left shift SL arrangement, the luminance at the angle of about −10 degrees can be the maximum. The maximum luminance can be about 96%, and the luminance at the angles of about +20 degrees and about −40 degrees can be about 1%.

Referring to FIG. 5 and FIG. 7 again, in the display device according to the implementation of the present disclosure of FIG. 5, the pixels in the first, second, third, fourth, and fifth regions A1, A2, A3, A4, and A5 can have the zero shift S0 arrangement, and the third viewing angle a3, which is the maximum viewing angle of the passenger, can correspond to the second region A2. Accordingly, since the passenger can view the part of the image of the second region A2, it is not easy to protect the privacy of the driver.

However, in the display device according to another implementation of the present disclosure, at least one pixel disposed at the center of the second region A2 can have the zero shift S0 arrangement, the pixels can gradually have the right shift SR arrangement from the center to the right edge of the second region A2, and the pixels can gradually have the left shift SL arrangement from the center to the left edge of the second region A2, thereby limiting the passenger's view to the second region A2 and allowing only the driver to view the image of the second region A2. Accordingly, the privacy of the driver can be protected.

As another example, at least one pixel disposed at the left edge of the second region A2 can have the zero shift S0 arrangement, the pixels can gradually have the left shift SL arrangement from the left edge to the right edge of the second region A2, thereby further limiting the passenger's view to the second region A2 and allowing only the driver to view the image of the second region A2. Accordingly, the privacy of the driver can be protected.

Meanwhile, in the pixels arranged in the third region A3 of FIG. 7, the positions of the emission area EA and the aperture AP can also differ depending on the locations.

For example, at least one pixel disposed at the center of the third region A3 can have the zero shift S0 arrangement. That is, as shown in FIG. 2 and FIG. 3, the aperture AP may not shift with respect to the emission area EA.

The pixel disposed at the right edge of the third region A3 can have the left shift SL arrangement. That is, the aperture AP can shift to the left with respect to the emission area EA.

In addition, the pixels disposed between the center and the right edge of the third region A3 can also have the left shift SL arrangement, and the degree of shift can gradually increase from the center to the right edge. That is, the degree of shift of the pixel adjacent to the center can be smallest, and the degree of shift of the pixel disposed at the right edge can be largest. In other words, the apertures AP from the center to the right edge of the third region A3 gradually shift to the right with respect to the emission areas EA.

On the other hand, the pixel disposed at the left edge of the third region A3 can have the right shift SR arrangement. That is, the aperture AP can shift to the right with respect to the emission area EA.

In addition, the pixels disposed between the center and the left edge of the third region A3 can also have the right shift SR arrangement, and the degree of shift can gradually increase from the center to the left edge. That is, the degree of shift of the pixel adjacent to the center can be smallest, and the degree of shift of the pixel disposed at the left edge can be largest. In other words, the apertures AP from the center to the left edge of the third region A3 gradually shift to the left with respect to the emission areas EA.

Here, the pixels of the third region A3 can have a structure that is symmetrical left and right with respect to the pixel arranged in the zero shift S0. In addition, the degrees of shift of the pixels of the third region A3 in the left-right direction, that is, the first direction X can all be different.

However, implementations of the present disclosure are not limited thereto. At least two pixels of the third region A3 adjacent to each other in the first direction X can have the same degree of shift.

As shown in FIG. 12B and FIG. 12C, when the third region A3 is configured such that the second viewing angle a2 is about 10 degrees, the luminance at the left and right edges of the third region A3 can be about 96%, which is higher than the luminance of about 77% at the left and right edges of the third region A3 in the display device of FIG. 5. Accordingly, the third region A3 of the display device according to another implementation of the present disclosure can have a uniform and high luminance compared to the display device of the previous implementation, and the passenger can view a higher quality image.

Meanwhile, in the display device according to another implementation of the present disclosure, the pixels in the first region A1, the fourth region A4 and the fifth region A5 can also have the shift arrangements. In this case, the pixels in the first region A1, the fourth region A4, and the fifth region A5 can have the left shift SL arrangement, and it is possible to optimize the driver's viewing conditions for the first region A1, the fourth region A4, and the fifth region A5.

As another example, the pixels in the fourth region A4 and the fifth region A5 can also have the following shift arrangements. In this case, the pixels in the fourth region A4 can have the right shift SR arrangement, and the fifth region A5 can have the left shift SL arrangement, and it is possible to further optimize the driver's viewing conditions for the fourth region A4 and the fifth region A5.

By providing the light control panel over the display panel, the display device of the present disclosure can selectively limit the viewing angle.

In addition, by differently shifting the light control panel with respect to the display panel by area and limiting the viewing according to the viewing position, the privacy of the viewer can be protected. The display device of the present disclosure can be applied to a vehicle to thereby protect the privacy of both the driver and the passenger.

Moreover, in the display device of the present disclosure, since the luminance for the passenger's viewing position can be improved, the improved luminance can reduce power consumption, thereby achieving the low power consumption.

It will be apparent to those skilled in the art that various modifications and variations can be made in the electroluminescent display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device provided with first, second, and third regions arranged sequentially in a first direction, each of the first, second, and third regions including a plurality of pixels, the display device comprising:
a display panel including an emission area corresponding to each pixel of the plurality of pixels in each of the first, second, and third regions; and
a light control panel over the display panel and including an aperture corresponding to the emission area for each pixel,
wherein for pixels located in different portions of the second region, locations of apertures corresponding to the pixels are differently arranged with respect to the emission areas for the pixels.

2. The display device of claim 1, wherein for a pixel located at a first edge of the second region adjacent to the first region, an aperture is arranged to be shifted left with respect to a corresponding emission area in a left-right direction parallel to the first direction, and wherein for a pixel located at a second edge of the second region adjacent to the third region, an aperture is arranged to be shifted right with respect to a corresponding emission area in the left-right direction.

3. The display device of claim 2, wherein for a pixel located at a center of the second region, an aperture is arranged without shift with respect to a corresponding emission area.

4. The display device of claim 3, wherein for pixels located from the center towards the first edge of the second region, apertures are arranged to be gradually shifted left with respect to corresponding emission areas, and
wherein for pixels located from the center towards the second edge of the second region, apertures are arranged to be gradually shifted right with respect to corresponding emission areas.

5. The display device of claim 3, wherein pixels of the second region are symmetrical left and right with respect to the center of the second region.

6. The display device of claim 1, wherein for a pixel located at a first edge of the second region adjacent to the third region, an aperture is arranged to be shifted left with respect to a corresponding emission area in a left-right direction parallel to the first direction, and
wherein for a pixel located at a second edge of the second region adjacent to the first region, an aperture is arranged without shift with respect to a corresponding emission area.

7. The display device of claim 6, wherein for pixels located from the second edge towards the first edge of the second region, apertures are arranged to be gradually shifted left with respect to corresponding emission areas in the left-right direction.

8. The display device of claim 1, wherein for a pixel located at a third edge of the third region adjacent to the second region, an aperture is arranged to be shifted right with respect to a corresponding emission area in a left-right direction parallel to the first direction, and
wherein for a pixel located at a fourth edge of the third region opposite to the third edge, an aperture is arranged to be shifted left with respect to a corresponding emission area in the left-right direction.

9. The display device of claim 8, wherein for a pixel located at a center of the third region, an aperture is arranged without shift with respect to a corresponding emission area,
wherein for pixels located from the center towards the third edge of the third region, apertures are arranged to be gradually shifted right with respect to corresponding emission areas, and
wherein for pixels located from the center towards the fourth edge of the third region, apertures are arranged to be gradually shifted left with respect to corresponding emission areas.

10. The display device of claim 8, wherein at least two pixels of the second region adjacent to each other in the first direction have the same degree of shift for apertures with respect to corresponding emission areas.

11. The display device of claim 1, wherein for pixels located in the first region, apertures are arranged to be shifted left with respect to corresponding emission areas in a left-right direction parallel to the first direction.

12. The display device of claim 1, further comprising a fourth region and a fifth region,
wherein the first, second, and third regions are disposed between the fourth region and the fifth region, and
wherein for pixels located in the fourth region and in the fifth region, apertures are arranged to be shifted left with respect to corresponding emission areas in a left-right direction parallel to the first direction.

13. The display device of claim 1, further comprising a fourth region and a fifth region,
wherein the first, second, and third regions are disposed between the fourth region and the fifth region, and the fourth region is adjacent to the first region and the fifth region is adjacent to the third region,
wherein for pixels located in the fourth region, apertures are arranged to be shifted right with respect to corresponding emission areas in the left-right direction and
for pixels located in the fifth region, apertures are arranged to be shifted left with respect to corresponding emission areas in the left-right direction.

14. The display device of claim 1, wherein the display panel includes a light-emitting diode constituting the emission area, and
wherein the light control panel includes a light-blocking layer constituting the aperture and a lens corresponding to the aperture.

15. The display device of claim 14, wherein the light-blocking layer is a sensor layer.

16. The display device of claim 14, wherein the light control panel further includes a black matrix between the light-blocking layer and the display panel, and
wherein the black matrix has an opening larger than the aperture.

17. The display device of claim 16, wherein, in at least a part of the display device, the black matrix, the light-blocking layer and the lens of the light control panel are shifted to left or right with respect to the light-emitting diode of the display panel in a left-right direction parallel to the first direction.

18. A display device comprising a plurality of pixels, the display device comprising:
a display panel including an emission area corresponding to each pixel of the plurality of pixels; and
a light control panel over the display panel and including an aperture corresponding to the emission area for each pixel,
wherein the display device further comprises a plurality of regions disposed sequentially in a first direction, wherein apertures corresponding to pixels in at least one of the plurality of regions are arranged to be shifted right or left with respect to corresponding emission areas in a left-right direction parallel to the first direction.

19. The display device of claim 18, wherein the plurality of regions comprises first, second, and third regions sequentially disposed in the first direction,
wherein for a pixel at a first edge of the second region adjacent to the first region, an aperture is arranged to be shifted left with respect to a corresponding emission area in the left-right direction, and
wherein for a pixel at a second edge of the second region adjacent to the third region, an aperture is arranged to be shifted right with respect to a corresponding emission area in the left-right direction.

20. The display device of claim 18, wherein the plurality of regions comprises first, second, and third regions sequentially disposed in the first direction, and
wherein for a pixel at a third edge of the third region adjacent to the second region, an aperture is arranged to be shifted right with respect to a corresponding emission area in the left-right direction, and
wherein for a pixel at a fourth edge of the third region opposite to the third edge, an aperture is arranged to be shifted left with respect to a corresponding emission area in the left-right direction.
